(19) United States
(12) Patent Application Publication
(10) Pub. No.: US 2026/0254263 A1
(43) Pub. Date: Aug. 27, 2026

(54) SYSTEM AND METHOD FOR MANAGING BATTERY

(71) Applicants: Hyundai Motor Company, Seoul (KR); Kia Corporation, Seoul (KR)

(72) Inventors: Donggil HA, Hwaseong-Si (KR); Yunjeong NAM, Hwaseong-Si (KR); Min-gyu PARK, Hwaseong-Si (KR); Jiyeong SEO, Hwaseong-Si (KR)

(21) Appl. No.: 19/284,073

(22) Filed: Jul. 29, 2025

(30) Foreign Application Priority Data
Feb. 21, 2025 (KR) 10-2025-0022850

(51) Int. Cl. H02J 7/00

(52) U.S. Cl. CPC H02J 7/52; H02J 7/82; H02J 7/84; H02J 7/96

(57) ABSTRACT

The present disclosure relates to a system and method for managing a battery. The system may include a sensor configured to sense a state of each of a plurality of battery cells in a battery; and a control circuit operatively connected to the sensor. The control circuit may be configured to perform cell balancing of the battery by sequentially adjusting, based on a state of charge (SOC) of the battery and a predetermined SOC range associated with the battery, a voltage of each of the plurality of battery cells to one of a maximum voltage of the plurality of battery cells or a minimum voltage of the plurality of battery cells.

### CROSS-REFERENCE TO RELATED APPLICATION

This present application claims the benefit of and priority to Korean Patent Application No. 10-2025-0022850, filed Feb. 21, 2025 in the Korean Intellectual Property Office, the entire disclosure of which is incorporated herein by reference.

### TECHNICAL FIELD

The present disclosure relates to a system and method for managing a battery, and more particularly, to a system and method for performing battery cell balancing.

### BACKGROUND

Environmentally friendly vehicles, such as electric vehicles (EVs), hybrid electric vehicles (HEVs), and plug-in hybrid electric vehicles (PHEVs), may be equipped high-voltage batteries that are capable of generating high voltage by connecting numerous battery cells of the same or similar specifications in series and/or parallel.

However, even battery cells of the same specification may become imbalanced due to manufacturing variations, changes in the properties of constituent materials (e.g., positive electrode materials and negative electrode materials) due to continuous charging and discharging cycles, battery cell degradation, and the like.

Such imbalance among battery cells may impact the capacity, performance, and lifespan of the battery and may increase the risk of fire due to overcharging and overdischarging. Accordingly, battery cell balancing is necessary to address the imbalance among battery cells.

The matters described in this Background section are only for enhancement of understanding of the background of the disclosure, and should not be taken as acknowledgement that they correspond to prior art already known to those skilled in the art.

### SUMMARY

The present disclosure is directed to providing a system and method for managing a battery capable of performing cell balancing while reducing voltage differences among battery cells.

The present disclosure is further directed to providing a system and method for managing a battery capable of cell balancing while preventing the most degraded cell from being continuously exposed to high or low voltage.

The present disclosure is still further directed to providing a system and method for managing a battery capable of performing cell balancing while considering battery usage patterns and target charge levels.

Objects of the present disclosure are not limited to the above-mentioned object, and other objects and advantages of the present disclosure, which are not mentioned, will be understood through the following description, and will become apparent from one or more example embodiments of the present disclosure. It is also to be understood that the objects and advantages of the present disclosure may be realized by means and combinations thereof set forth in claims.

According to one or more example embodiments of the present disclosure, a system may include: a sensor configured to sense a state of each of a plurality of battery cells in a battery; and a control circuit operatively connected to the sensor. The control circuit may be configured to: perform cell balancing of the battery by sequentially adjusting, based on a state of charge (SOC) of the battery and a predetermined SOC range associated with the battery, a voltage of each of the plurality of battery cells to one of a maximum voltage of the plurality of battery cells or a minimum voltage of the plurality of battery cells.

The control circuit may be configured to perform the cell balancing by: adjusting, based on an inter-cell voltage deviation of the plurality of battery cells being greater than or equal to a predetermined voltage deviation, the voltage of each of the plurality of battery cells to the minimum voltage of the plurality of battery cells. The inter-cell voltage deviation may be a difference between the maximum voltage of the plurality of battery cells and the minimum voltage of the plurality of battery cells.

The control circuit may be further configured to determine, among the plurality of battery cells, a first group of battery cells. Each of the first group of battery cells may have a state of health (SOH) within a predetermined SOH deviation from a maximum SOH of the plurality of battery cells.

The control circuit may be further configured to: select, from the first group of battery cells, a battery cell that has not been previously selected; and determine a cell balancing target voltage according to an equation:

$$CBtgt = \vert {Cell}_{now} - {DEV}_{SOH} \vert ,$$

where CBtgt is the cell balancing target voltage, Cellnow is a voltage of the selected cell, and DEV_{SOH} is the predetermined voltage deviation.

The control circuit may be is further configured to: determine, based on a first SOC at a start of a charging operation for the battery and a second SOC at an end of the charging operation, an average SOC usage range of the battery.

The control circuit may be configured to perform the cell balancing by: performing the cell balancing on the selected cell until the cell balancing target voltage is reached, based on a degradation rate at the SOC of the battery satisfying an inequality, the SOC of the battery during discharging reaching a first reference value, and the inter-cell voltage deviation being less than the predetermined voltage deviation. The inequality may be defined by:

$$f ( {SOC}_{L} ) \geq max ( f ( {SOC}_{tgt} ) , f ( {SOC}_{U} ) ) ,$$

where SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and max(f(SOC_{tgt}), f(SOC_{U})) is a maximum of f(SOC_{tgt}) and f(SOC_{U}).

The first reference value may be the lower limit of the average SOC usage range.

The control circuit may be configured to perform the cell balancing by: performing the cell balancing on remaining cells, other than the selected cell, in the first group of battery cells until the cell balancing target voltage is reached, based on a degradation rate at the SOC of the battery satisfying an inequality, the SOC of the battery during charging reaching a second reference value, and the inter-cell voltage deviation being less than the predetermined voltage deviation. The inequality may be defined by:

$$f ( {SOC}_{L} ) < min ( f ( {SOC}_{tgt} ) , f ( {SOC}_{U} ) ) ,$$

where SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and min(f(SOC_{tgt}), f(SOC_{U})) is a minimum of f(SOC_{tgt}) and f(SOC_{U}).

The second reference value may be set to be the predetermined target SOC based on a degradation rate at the upper limit of the average SOC usage range being lower than a degradation rate at the predetermined target SOC.

The second reference value may be set to be the upper limit of the average SOC usage range based on a degradation rate at the upper limit of the average SOC usage range being greater than a degradation rate at the predetermined target SOC.

According to one or more example embodiments of the present disclosure, a method performed by an apparatus for managing a battery may include: sensing, via a sensor, a state of each of a plurality of battery cells in the battery; and performing cell balancing of the battery by sequentially adjusting, based on a state of charge (SOC) of the battery and a predetermined SOC range associated with the battery, a voltage of each of the plurality of battery cells to one of a maximum voltage of the plurality of battery cells or a minimum voltage of the plurality of battery cells.

Performing the cell balancing may include: adjusting, based on an inter-cell voltage deviation of the plurality of battery cells being greater than or equal to a predetermined voltage deviation, the voltage of each of the plurality of battery cells to the minimum voltage of the plurality of battery cells. The inter-cell voltage deviation may be a difference between the maximum voltage of the plurality of battery cells and the minimum voltage of the plurality of battery cells.

The method may further include: determining, among the plurality of battery cells, a first group of battery cells. Each of the first group of battery cells may have a state of health (SOH) within a predetermined SOH deviation from a maximum SOH of the plurality of battery cells.

The method may further include: selecting, from the first group of battery cells, a battery cell that has not been previously selected; and determining a cell balancing target voltage according to an equation:

$${CB}_{tgt} = \vert {Cell}_{now} - {DEV}_{SOH} \vert ,$$

where CB_{tgt} is the cell balancing target voltage, Cell_{now} is a voltage of the selected cell, and DEV_{SOH} is the predetermined voltage deviation.

The method may further include: determining, based on a first SOC at a start of a charging operation for the battery and a second SOC at an end of the charging operation, an average SOC usage range of the battery.

Performing the cell balancing may include: performing the cell balancing on the selected cell until the cell balancing target voltage is reached, based on a degradation rate at the SOC of the battery satisfying an inequality, the SOC of the battery during discharging reaching a first reference value, and the inter-cell voltage deviation being less than the predetermined voltage deviation. The inequality may be defined by:

$$f ( {SOC}_{L} ) \geq max ( f ( {SOC}_{tgt} ) , f ( {SOC}_{U} ) ) ,$$

where SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and max(f(SOC_{tgt}), f(SOC_{U})) is a maximum of f(SOC_{tgt}) and f(SOC_{U}).

The first reference value may be the lower limit of the average SOC usage range.

Performing the cell balancing may include: performing the cell balancing on remaining cells, other than the selected cell, in the first group of battery cells until the cell balancing target voltage is reached based on a degradation rate at the SOC of the battery satisfying an inequality, the SOC of the battery during charging reaching a second reference value, and the inter-cell voltage deviation being less than the predetermined voltage deviation. The inequality may be defined by:

$$f ( {SOC}_{L} ) < min ( f ( {SOC}_{tgt} ) , f ( {SOC}_{U} ) ) ,$$

where SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and min(f(SOC_{tgt}), f(SOC_{U})) is a minimum of f(SOC_{tgt}) and f(SOC_{U}).

The second reference value may be set to be the predetermined target SOC based on a degradation rate at the upper limit of the average SOC usage range being lower than a degradation rate at the predetermined target SOC. The second reference value may be set to be the upper limit of the average SOC usage range based on a degradation rate at the upper limit of the average SOC usage range being greater than a degradation rate at the predetermined target SOC.

According to one or more example embodiments of the present disclosure, a battery system may include: a sensor configured to sense states of a plurality of battery cells in a battery; and a control circuit operatively connected to the sensor. The control circuit may be configured to: detect at least one first battery cell, of the plurality of battery cells, associated with a first battery cell state, and detect at least one second battery cell, of the plurality of battery cells, associated with a second battery cell state; and perform cell balancing of the battery by sequentially adjusting a voltage of each of the at least one second battery cell to one of a maximum voltage of the plurality of battery cells or a minimum voltage of the plurality of battery cells, such that a voltage of each of the at least one first battery cell does not correspond to the maximum voltage or the minimum voltage.

### BRIEF DESCRIPTION OF THE DRAWINGS

The foregoing and other aspects, features, and advantages, as well as the following detailed description of the example embodiment(s), will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a block diagram illustrating a configuration of a battery management system.

FIG. 2 is a flowchart illustrating an example battery management method.

FIGS. 3A and 3B are graphs illustrating the voltage of each battery cell before and after applying a battery management method.

FIG. 4A, FIG. 4B, FIG. 4C, and FIG. 4D are graphs sequentially illustrating a battery management method.

FIG. 5 shows an example interface for setting the target SOC amount as one of the battery parameters.

FIG. 6 is a graph illustrating the battery degradation degree before and after applying an example battery management method.

FIG. 7 shows an example computing system.

### DETAILED DESCRIPTION

Hereinafter, reference will be made in detail to one or more example embodiments of the present disclosure, examples of which are illustrated in the accompanying drawings and described below, and wherever possible, the same or similar elements will be denoted by the same reference numerals even though they are depicted in different drawings and a redundant description thereof will thus be omitted. In the following description of the example embodiment(s), suffixes, such as “module”, and “part”, are provided or used interchangeably merely in consideration of ease in statement of the specification, and do not have meanings or functions distinguished from one another. In the following description of the example embodiment(s) of the present disclosure, a detailed description of known functions and configurations incorporated herein will be omitted when it may make the subject matter of the present disclosure rather unclear. Further, the accompanying drawings will be exemplarily given to describe the example embodiment(s) of the present disclosure, and should not be construed as being limited to the example embodiment(s) set forth herein, and it will be understood that the example embodiment(s) of the present disclosure are provided only to completely disclose the disclosure and cover modifications, equivalents or alternatives which come within the scope and technical range of the disclosure.

In the following description of the example embodiment(s), terms, such as “first” and “second”, are used only to describe various elements, and these elements should not be construed as being limited by these terms. These terms are used only to distinguish one element from other elements.

When an element or layer is referred to as being “connected to” or “coupled to” another element or layer, it may be directly connected or coupled to the other element or layer, or intervening elements or layers may be present. In contrast, when an element or layer is referred to as being “directly connected to” or “directly coupled to” another element or layer, there may be no intervening elements or layers present.

For purposes of the present application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a compact disc ROM (CD-ROM) or a digital video disc (DVD), magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

Battery cell balancing in at least some implementations is performed by measuring the voltage of each of a plurality of battery cells and either dissipating the excess energy of higher-voltage battery cells to match the voltage of the lowest-voltage battery cell, or transferring the excess energy of higher-voltage battery cells to lower-voltage battery cells to equalize the voltage of all battery cells.

However, in these implementations, the battery cell balancing is performed without considering the fact that a cell with a low state of health (SOH) is frequently exposed to relatively high or low voltage. As a result, voltage deviations and state of charge (SOC) deviations caused by SOH differences among battery cells may not be taken into account. Consequently, degradation factors may become concentrated in the most deteriorated battery cell, accelerating the decline in output of the entire battery module or battery pack.

Additionally, the battery cell balancing in some of these implementations may be performed without considering a user's battery usage pattern or target charge level, potentially causing it to be uniformly triggered based on predefined reference values. Consequently, in highly degraded regions, cell balancing may be delayed, or alternatively, performed unnecessarily, leading to increased energy consumption of battery cells and adversely affecting the performance and lifespan of the entire battery module or battery pack.

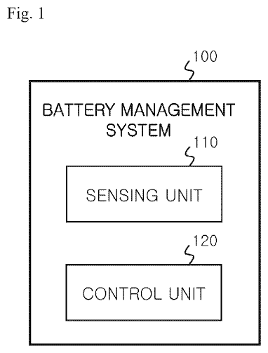

A battery management system and method according to the present disclosure are described in detail below with reference to FIG. 1 to FIG. 6.

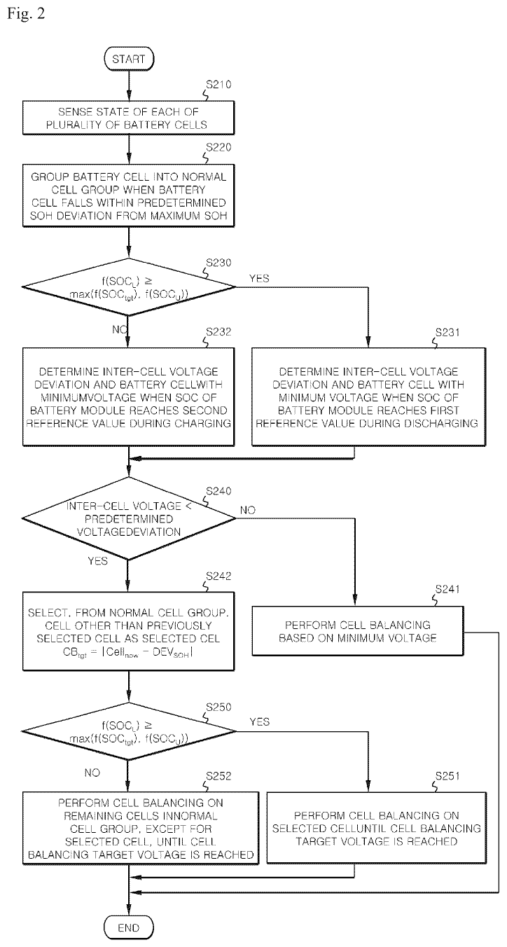

FIG. 1 is a block diagram illustrating a configuration of a battery management system, and FIG. 2 is a flowchart illustrating an example battery management method.

Referring to FIG. 1, a battery management system 100 may include a sensing unit (e.g., one or more sensors) 110, a control unit (also referred to as a controller) 120, and the like.

The sensing unit 110 senses a state of each of a plurality of battery cells constituting one or more battery modules (also referred to as batteries or battery arrays) included in the battery pack (see S210 of FIG. 2).

For example, the sensing unit 110 may periodically measure the current, voltage, temperature, and SOC of each battery cell.

The plurality of battery cells store energy and may be configured to be rechargeable for reuse.

The battery management method in some implementations may aim to reduce the voltage of each cell with a voltage higher than the lowest battery cell voltage to equalize all cell voltages within the battery system.

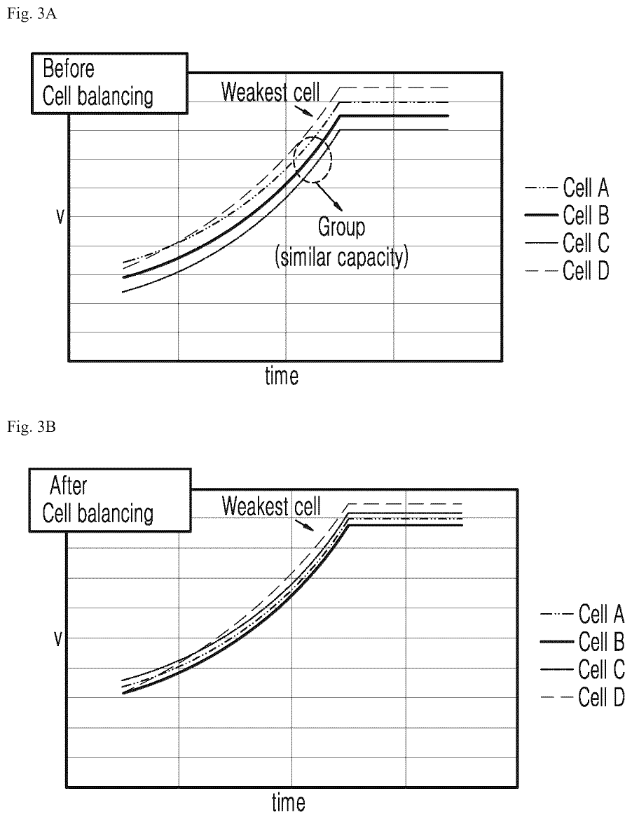

In this regard, FIG. 3A is a graph illustrating the voltage of each battery cell before the application of the battery management method according to at least some implementations. FIG. 3B is a graph illustrating the voltage of each battery cell after the application of the battery management method according to some of these implementations.

As shown in FIGS. 3A and 3B, even after the application of the battery management method, the most degraded Cell D may remain continuously exposed to high voltage compared to other cells, potentially accelerating its degradation.

The control unit 120 may operate in conjunction with the sensing unit and perform cell balancing to sequentially adjust the voltage of each battery cell to the maximum or minimum voltage based on the state of charge (SOC) of the battery module and a predetermined SOC range.

For example, the control unit 120 may include an energy storage element and a switch, and may be configured to transfer energy from a battery cell with a higher voltage to a battery cell with a lower voltage, ensuring that the voltage of each cell is balanced.

Alternatively, the control unit 120 may be configured to reduce the voltage of the battery cell with the higher voltage to match the voltage of the battery cell with the lower voltage.

First, the control unit (120) may be configured to group at least one battery cell among the plurality of battery cells as part of a normal cell group when its state of health (SOH) falls within a predetermined SOH deviation from the maximum SOH of the plurality of battery cells (see S220 of FIG. 2).

The normal cell group may include two or more subgroups, such as Group A and Group B, based on the degradation level.

The predetermined SOH deviation may be determined based on the distribution data of cell capacity.

The control unit 120 may be configured to determine an average SOC usage range based on the SOC at the start of charging and the SOC at the end of charging for the battery module.

For example, actual battery usage data may be collected, and the collected data may be averaged or statistically processed to determine the average SOC usage range.

Hereinafter, the lower limit of the average SOC usage range will be referred to as a first reference value, and the upper limit of the average SOC usage range will be referred to as a second reference value.

The battery undergoes accelerated degradation due to factors such as high or low SOC and high or low voltage; however, the extent of degradation may vary across different SOC and voltage ranges.

A degradation rate function may be derived based on the degradation rate per cycle for each voltage and SOC, using storage degradation tests, degradation models, and the like. Alternatively, the degradation rate function may be derived based on the degradation rate per unit time for each voltage or SOC.

Using the degradation rate function, the control unit 120 may determine the degradation rate at either the battery module's SOC or voltage, or both. The input parameters for the degradation rate function are not limited to SOC alone but may also include voltage, temperature, and other factors.

When the SOC of a battery module is determined to deviate from the average SOC usage range derived based on the user's battery usage pattern, cell balancing may be performed.

The control unit 120 may detect when the SOC of the battery module decreases below the first reference value during discharging or increases above the second reference value during charging (see S230 of FIG. 2).

Hereinafter, the difference between the maximum voltage and the minimum voltage of the plurality of battery cells is referred to as an inter-cell voltage deviation.

First, when the degradation rate at the SOC of the battery module satisfies Inequality 1 below and the SOC of the battery module has reached the first reference value during discharging while the inter-cell voltage deviation is less than the predetermined voltage deviation, the inter-cell voltage deviation and the voltage of the battery cell with the minimum voltage are determined (see S231 of FIG. 2).

f(SOC_{L})≥max(f(SOC_{tgt}), f(SOC_{U})) [Inequality 1]
wherein SOC_{L} is a lower limit of the average SOC usage range, SOC_{U} is an upper limit of the average SOC usage range, SOC_{tgt} is a predetermined target SOC amount, f() is a degradation rate function of the SOC, f(SOC_{L}) is the degradation rate at SOC_{L}, f(SOC_{tgt}) is the degradation rate at SOC_{tgt}, f(SOC_{U}) is the degradation rate at SOC_{U}, and max(f(SOC_{tgt}), f(SOC_{U})) is a maximum of f(SOC_{tgt}) and f(SOC_{U}).

The predetermined target SOC amount is an input parameter set by the user.

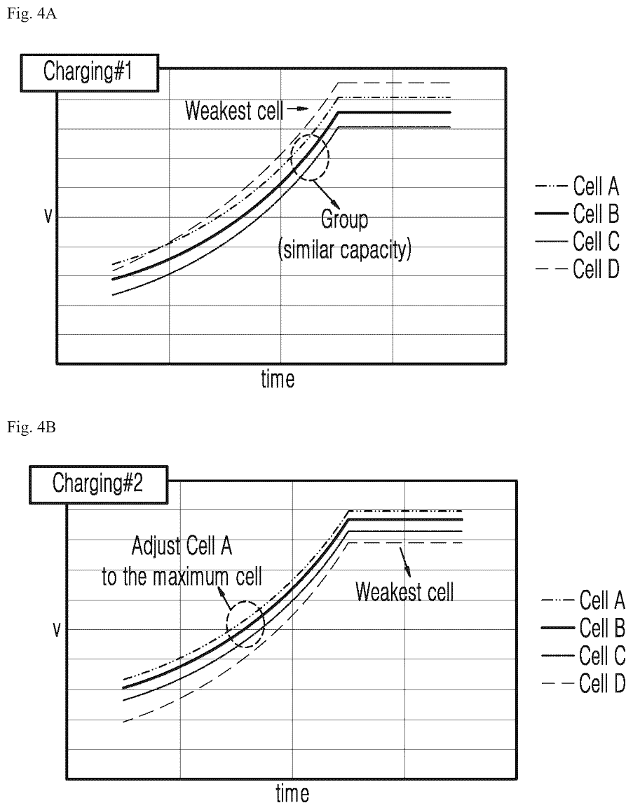

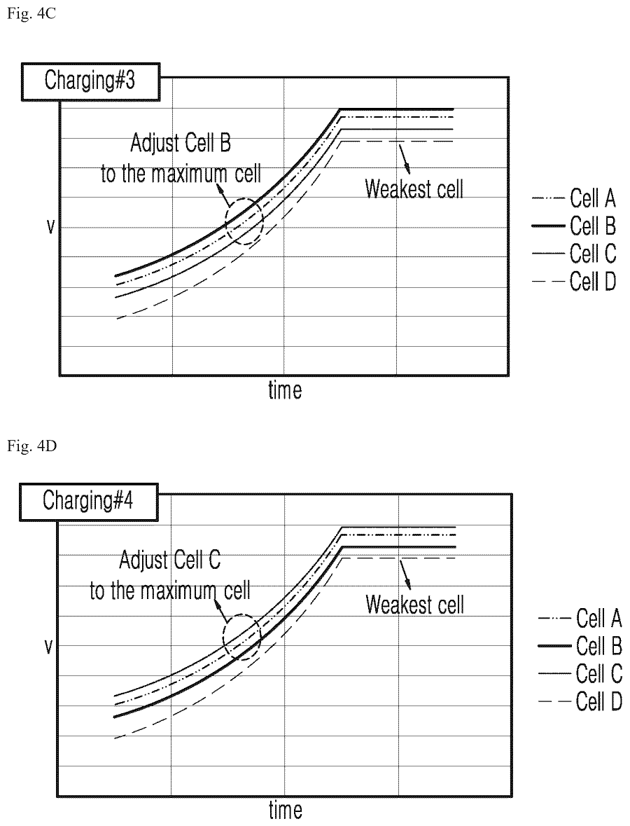

FIG. 4A is a graph sequentially illustrating a battery management method.

FIG. 4A is a graph illustrating the voltage of each battery cell when the inter-cell voltage deviation is equal to or greater than the predetermined voltage deviation and the SOC of the battery module reaches the second reference value during charging.

FIG. 4B illustrates the result after designating Cell A as a selected cell in FIG. 4A and performing cell balancing on the other cells based on a cell balancing target voltage.

FIG. 4C illustrates the result after designating Cell B as a selected cell in FIG. 4B and performing cell balancing on the other cells based on a cell balancing target voltage.

FIG. 4D illustrates the result after designating Cell C as a selected cell in FIG. 4C and performing cell balancing on the other cells based on a cell balancing target voltage.

Within a battery system, electrical, thermal, and mechanical imbalances exist, preventing all cells from degrading uniformly. As a result, inter-cell voltage deviation may persist as degradation progresses.

The lifespan of the battery system is determined by the most degraded cell among all battery cells in the battery system, so it is important to redistribute the degradation factors based on the degradation level of each cell. When a specific cell is frequently exposed to degradation factors, the lifespan of the battery system is shortened at an accelerated rate.

Therefore, redistributing the degradation factors concentrated on the specific cell to other cells may extend the lifespan of the battery system.

As shown in FIGS. 4A, 4B, 4C, and 4D, Cell D, which has the highest degradation level, is excluded from the normal group unlike Cells A, B, and C. Consequently, it is not designated as the selected cell, thereby reducing its exposure to degradation factors.

The battery management method may have the effect of preventing the most degraded cell from being exposed to high voltage, thereby slowing the degradation progress of the most degraded cell, and thus extending the lifespan of the high-voltage battery system.

If the degradation rate at the SOC of the battery module satisfies Inequality 2 below, and the SOC of the battery module has reached the second reference value during charging while the inter-cell voltage deviation is less than the predetermined voltage deviation, a control unit may determine the inter-cell voltage deviation and the voltage of the battery cell with the minimum voltage (see S232 of FIG. 2).

f(SOC_{L})<min(f(SOC_{tgt}), f(SOC_{U})) [Inequality 2]
wherein SOC_{L} is a lower limit of the average SOC usage range, SOC_{U} is an upper limit of the average SOC usage range, SOC_{tgt} is a predetermined target SOC amount, f() is a degradation rate function of the SOC, f(SOC_{L}) is the degradation rate at SOC_{L}, f(SOC_{tgt}) is the degradation rate at SOC_{tgt}, f(SOC_{U}) is the degradation rate at SOC_{U}, and min(f(SOC_{tgt}), f(SOC_{U})) is the minimum of f(SOC_{tgt}) and f(SOC_{U}).

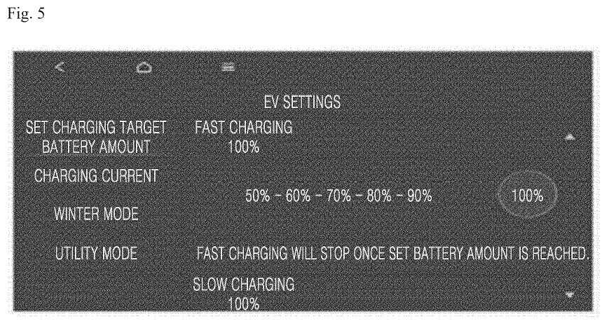

FIG. 5 shows an example interface for setting the target SOC amount as one of the battery parameters.

As shown in FIG. 5, the user may set the SOC amount so that charging terminates when the SOC reaches the predetermined level based on fast or slow charging.

Next, the control unit 120 compares the inter-cell voltage deviation with the predetermined voltage deviation (see S240 of FIG. 2).

The control unit 120 determines that a fault condition exists when the inter-cell voltage deviation is equal to or greater than the predetermined voltage deviation, and performs cell balancing based on the minimum voltage (see S241 of FIG. 2).

The battery management method may prevent a cell with a low SOH from being exposed to degradation factors in a SOC range where a higher degree of degradation is determined, when the inter-cell voltage deviation is less than the predetermined voltage deviation.

That is, when the inter-cell voltage deviation is less than the predetermined voltage deviation, and the SOC of the battery module reaches the first reference value during discharging or the second reference value during charging, the control unit 120 selects, from the normal cell group, a cell other than the previously selected cell as the selected cell and determines the cell balancing target voltage using Equation 3 below (see S242 of FIG. 2).

The second reference value is set to the predetermined target SOC amount when the degradation rate at the upper limit of the average SOC usage range is lower than the degradation rate at the predetermined target SOC amount.

The second reference value is set to the upper limit of the average SOC usage range when the degradation rate at the upper limit of the average SOC usage range is greater than the degradation rate at the predetermined target SOC amount.

CB_{tgt}=|Cell_{now}−DEV_{SOH}| [Equation 3]
wherein CB_{tgt} is the cell balancing target voltage, Cell_{now} is a voltage of the selected cell, and DEV_{SOH} is the predetermined voltage deviation.

The control unit 120 performs cell balancing on the selected cell until the cell balancing target voltage is reached when the inter-cell voltage deviation is less than the predetermined voltage deviation and the SOC of the battery module reaches the first reference value during discharging (see S250 and S251 of FIG. 2).

When the SOC of the battery module reaches the second reference value during charging, the control unit 120 performs cell balancing on the remaining cells in the normal cell group, except for the selected cell, until the cell balancing target voltage is reached (see S250 and S252 of FIG. 2).

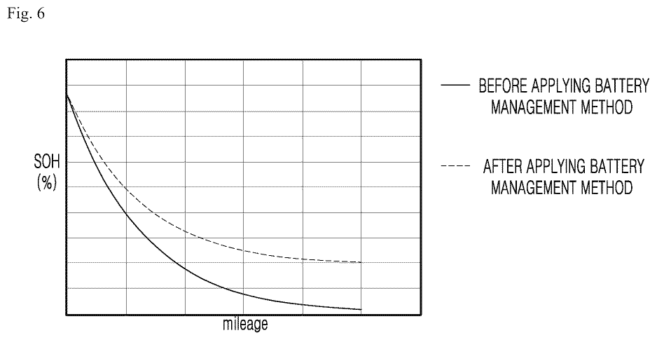

FIG. 6 is a graph illustrating the battery degradation degree before and after applying a battery management method.

As shown in FIG. 6, the lifespan of the high-voltage battery system may be extended by preventing a specific cell from being frequently exposed to degradation factors, thereby slowing the degradation progress of the most degraded cell.

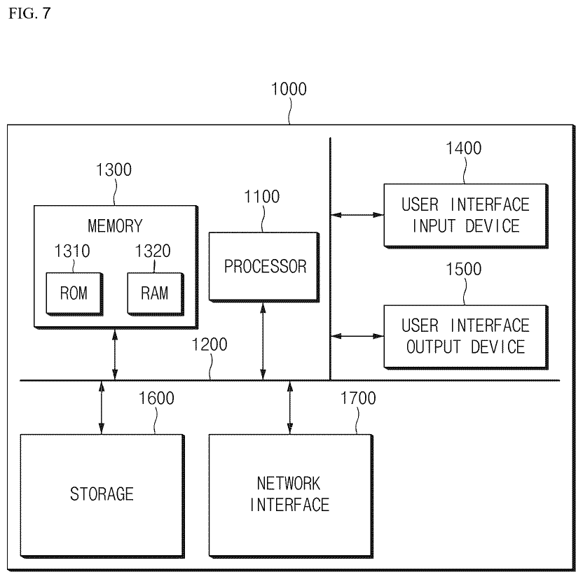

FIG. 7 shows an example computing system (e.g., a computing device of a vehicle or any other apparatus). One or more controllers, processors, etc. described herein may be implemented by the computing system or may be implemented in the computing system. For example, one or more of the battery management system 100, the sensor 110, the controller 120, etc. may be implemented with a computing system 1000 as shown in FIG. 7.

The computing system (also referred as a computer, a computing device, etc.) 1000 may include at least one processor 1100, memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read-only memory (ROM) and a random access memory (RAM).

Communication interface(s) (also referred to as communication device(s), communicator(s), communication module(s), communication unit(s), etc.), such as the network interface 1700, may allow software and/or data to be transferred between a device and one or more external devices, and/or between one or more components of a device. Communication interface(s) may include a receiver, a transmitter, a transceiver, a modem, a network interface and/or adapter (such as an Ethernet adapter), a radio transceiver, an antenna, a communication port, a Personal Computer Memory Card International Association (PCMCIA) slot and card, or the like. Software and data transferred via communication interface(s) may be in the form of signals, which may be electronic, electromagnetic, optical, infrared, or other signals capable of being received by communication interface(s). These signals may be provided to communication interface(s) via a communication path of a device, which may be implemented using, for example, wire or cable, fiber optics, a cellular link, a radio frequency (RF) link and/or other communications channels. Communication interface(s) may communicate using one or more communication protocols, such as Ethernet, Wi-Fi, near-field communication (NFC), Infrared Data Association (IrDA), Bluetooth, Bluetooth low energy (BLE), Zigbee, Long-Term Evolution (LTE), 5G New Radio (NR), vehicle-to-everything (V 2X), a controller area network (CAN), or a local interconnect network (LIN), etc.

The operations of the method or algorithm described in connection with example embodiment(s) disclosed in the specification may be directly implemented with a hardware module, a software module, or a combination of the hardware module and the software module, which is executed by the processor 1100. The software module may reside on a storage medium (i.e., the memory 1300 and/or the storage 1600) such as RAM, a flash memory, ROM, an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

An aspect of the present disclosure may include a sensing unit configured to sense a state of each of a plurality of battery cells in a battery module, and a control unit operatively connected to the sensing unit, wherein the control unit is configured to sequentially adjust voltages of the plurality of battery cells to a maximum voltage or a minimum voltage through cell balancing based on a state of charge (SOC) of the battery module and a predetermined SOC range.

The control unit may be configured to perform cell balancing based on the minimum voltage of a plurality of battery cells when an inter-cell voltage deviation is equal to or greater than a predetermined voltage deviation, the inter-cell voltage deviation being the difference between the maximum voltage and the minimum voltage of the plurality of battery cells.

The control unit may be configured to group at least one battery cell among the plurality of battery cells as part of a normal cell group when a state of health (SOH) of the at least one battery cell falls within a predetermined SOH deviation from the maximum SOH of the plurality of battery cells.

The control unit may be configured to determine an average SOC usage range based on SOC at a start of charging and SOC at an end of charging for the battery module.

Another aspect of the present disclosure may include sensing a state of each of a plurality of battery cells in a battery module by a sensing unit, and controlling the battery module by a control unit operatively connected to the sensing unit, wherein the control unit may be configured to sequentially adjust a voltage of each battery cell to a maximum voltage or a minimum voltage through cell balancing based on a state of charge (SOC) of the battery module and a predetermined SOC range.

The control unit may be configured to perform cell balancing based on the minimum voltage of a plurality of battery cells when an inter-cell voltage deviation is equal to or greater than a predetermined voltage deviation, the inter-cell voltage deviation being the difference between the maximum voltage and the minimum voltage of the plurality of battery cells.

The control unit may be configured to group at least one battery cell among the plurality of battery cells as part of a normal cell group when a state of health (SOH) of the at least one battery cell falls within a predetermined SOH deviation from the maximum SOH of the plurality of battery cells.

The control unit may be configured to determine an average SOC usage range based on SOC at a start of charging and SOC at an end of charging for the battery module.

The cell balancing according to the present disclosure may reduce voltage differences among battery cells, thereby enhancing battery capacity and extending lifespan.

In addition, the cell balancing according to the present disclosure may have the effect of preventing the degradation of battery cell by ensuring that the most degraded cell is not continuously exposed to high or low voltage.

Further, the cell balancing according to the present disclosure may have the effect of increasing the usage efficiency of the battery pack and extending its lifespan by considering battery usage patterns and target charge levels, and by reflecting individual user patterns and targets.

The present disclosure described as above is not limited by the aspects described herein and the accompanying drawings. It should be apparent to those skilled in the art that various substitutions, changes and modifications which are not exemplified herein but are still within the spirit and scope of the present disclosure may be made. Therefore, the scope of the present disclosure is defined not by the detailed description, but by the claims and their equivalents, and all variations within the scope of the claims and their equivalents are to be construed as being included in the present disclosure.

In the specification (particularly, in the claims) of the present disclosure, use of the term “above” and similar referential terms may refer to both the singular and the plural. In addition, when a range is stated in the present disclosure, any or all individual values within the range may be selected (unless there is a statement to the contrary).

Unless there is a statement of an explicit order or a statement to the contrary regarding steps constituting the method according to the present disclosure, the steps may be performed in any appropriate order. The present disclosure is not necessarily limited by the described order of the steps. Use of any examples or illustrative terms (for example, etc.) in the present disclosure is merely to describe the present disclosure in detail, and unless limited by the claims, the scope of the present disclosure is not limited by the examples or illustrative terms. Further, those skilled in the art will appreciate that various modifications, combinations, and changes may be made according to design conditions and factors within the scope of the appended claims or their equivalents.

Therefore, the spirit of the present disclosure should not be limited to the above-described example embodiment(s), and the scope of the appended claims described below as well as all scopes equivalent to or equivalently changed from the claims are within the scope of the spirit of the present disclosure.

What is claimed is:

1. A system comprising:
a sensor configured to sense a state of each of a plurality of battery cells in a battery; and
a control circuit operatively connected to the sensor,
wherein the control circuit is configured to:
perform cell balancing of the battery by sequentially adjusting, based on a state of charge (SOC) of the battery and a predetermined SOC range associated with the battery, a voltage of each of the plurality of battery cells to one of a maximum voltage of the plurality of battery cells or a minimum voltage of the plurality of battery cells.

2. The system of claim 1, wherein the control circuit is configured to perform the cell balancing by:
adjusting, based on an inter-cell voltage deviation of the plurality of battery cells being greater than or equal to a predetermined voltage deviation, the voltage of each of the plurality of battery cells to the minimum voltage of the plurality of battery cells, wherein the inter-cell voltage deviation is a difference between the maximum voltage of the plurality of battery cells and the minimum voltage of the plurality of battery cells.

3. The system of claim 2, wherein the control circuit is further configured to determine, among the plurality of battery cells, a first group of battery cells, wherein each of the first group of battery cells has a state of health (SOH) within a predetermined SOH deviation from a maximum SOH of the plurality of battery cells.

4. The system of claim 3, wherein the control circuit is further configured to:
select, from the first group of battery cells, a battery cell that has not been previously selected; and
determine a cell balancing target voltage according to an equation,
$${CB}_{tgt} = \vert {Cell}_{now} - {DEV}_{SOH} \vert$$
wherein CB_{tgt} is the cell balancing target voltage, Cell_{now} is a voltage of the selected cell, and DEV_{SOH} is the predetermined voltage deviation.

5. The system of claim 4, wherein the control circuit is further configured to:
determine, based on a first SOC at a start of a charging operation for the battery and a second SOC at an end of the charging operation, an average SOC usage range of the battery.

6. The system of claim 5, wherein the control circuit is configured to perform the cell balancing by:
performing the cell balancing on the selected cell until the cell balancing target voltage is reached, based on a degradation rate at the SOC of the battery satisfying an inequality, the SOC of the battery during discharging reaching a first reference value, and the inter-cell voltage deviation being less than the predetermined voltage deviation, wherein the inequality is defined by:
$$f ( {SOC}_{L} ) \geq max ( f ( {SOC}_{tgt} ) , f ( {SOC}_{U} ) )$$
wherein SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and max(f(SOC_{tgt}), f(SOC_{U})) is a maximum of f(SOC_{tgt}) and f(SOC_{U}).

7. The system of claim 6, wherein the first reference value is the lower limit of the average SOC usage range.

8. The system of claim 5, wherein the control circuit is configured to perform the cell balancing by:
performing the cell balancing on remaining cells, other than the selected cell, in the first group of battery cells until the cell balancing target voltage is reached, based on a degradation rate at the SOC of the battery satisfying an inequality, the SOC of the battery during charging reaching a second reference value, and the inter-cell voltage deviation being less than the predetermined voltage deviation, wherein the inequality is defined by:
$$f ( {SOC}_{L} ) < min ( f ( {SOC}_{tgt} ) , f ( {SOC}_{U} ) )$$
wherein SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and min(f(SOC_{tgt}), f(SOC_{U})) is a minimum of f(SOC_{tgt}) and f(SOC_{U}).

9. The system of claim 8, wherein the second reference value is set to be the predetermined target SOC based on a degradation rate at the upper limit of the average SOC usage range being lower than a degradation rate at the predetermined target SOC.

10. The system of claim 8, wherein the second reference value is set to be the upper limit of the average SOC usage range based on a degradation rate at the upper limit of the average SOC usage range being greater than a degradation rate at the predetermined target SOC.

11. A method performed by an apparatus for managing a battery, the method comprising:
sensing, via a sensor, a state of each of a plurality of battery cells in the battery; and
performing cell balancing of the battery by sequentially adjusting, based on a state of charge (SOC) of the battery and a predetermined SOC range associated with the battery, a voltage of each of the plurality of battery cells to one of a maximum voltage of the plurality of battery cells or a minimum voltage of the plurality of battery cells.

12. The method of claim 11, wherein the performing of the cell balancing comprises:
adjusting, based on an inter-cell voltage deviation of the plurality of battery cells being greater than or equal to a predetermined voltage deviation, the voltage of each of the plurality of battery cells to the minimum voltage of the plurality of battery cells, wherein the inter-cell voltage deviation is a difference between the maximum voltage of the plurality of battery cells and the minimum voltage of the plurality of battery cells.

13. The method of claim 12, further comprising:
determining, among the plurality of battery cells, a first group of battery cells, wherein each of the first group of battery cells has a state of health (SOH) within a predetermined SOH deviation from a maximum SOH of the plurality of battery cells.

14. The method of claim 13, further comprising:
selecting, from the first group of battery cells, a battery cell that has not been previously selected; and
determining a cell balancing target voltage according to an equation,
$${CB}_{tgt} = \vert {Cell}_{now} - {DEV}_{SOH} \vert$$
wherein CB_{tgt} is the cell balancing target voltage, Cell_{now} is a voltage of the selected cell, and DEV_{SOH} is the predetermined voltage deviation.

15. The method of claim 14, further comprising:
determining, based on a first SOC at a start of a charging operation for the battery and a second SOC at an end of the charging operation, an average SOC usage range of the battery.

16. The method of claim 15, wherein the performing of the cell balancing comprising:
performing the cell balancing on the selected cell until the cell balancing target voltage is reached, based on a degradation rate at the SOC of the battery satisfying an inequality, the SOC of the battery during discharging reaching a first reference value, and the inter-cell voltage deviation being less than the predetermined voltage deviation, wherein the inequality is defined by:
$$f ( {SOC}_{L} ) \geq max ( f ( {SOC}_{tgt} ) , f ( {SOC}_{U} ) )$$
wherein SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and max(f(SOC_{tgt}), f(SOC_{U})) is a maximum of f(SOC_{tgt}) and f(SOC_{U}).

17. The method of claim 16, wherein the first reference value is the lower limit of the average SOC usage range.

18. The method of claim 15, wherein the performing of the cell balancing comprises:
performing the cell balancing on remaining cells, other than the selected cell, in the first group of battery cells until the cell balancing target voltage is reached based on a degradation rate at the SOC of the battery satisfying an inequality, the SOC of the battery during charging reaching a second reference value, and the inter-cell voltage deviation being less than the predetermined voltage deviation, wherein the inequality is defined by:
f(SOC_{L})<min(f(SOC_{tgt}), f(SOC_{U}))
wherein SOC_{L} is a lower limit of the average SOC usage range, SOC_{U} is an upper limit of the average SOC usage range, SOC_{tgt} is a predetermined target SOC, f() is a degradation rate function of the SOC, f(SOC_{L}) is a degradation rate at SOC_{L}, f(SOC_{tgt}) is a degradation rate at SOC_{tgt}, f(SOC_{U}) is a degradation rate at SOC_{U}, and min(f(SOC_{tgt}), f(SOC_{U})) is a minimum of f(SOC_{tgt}) and f(SOC_{U}).

19. The method of claim 18, wherein:
the second reference value is set to be the predetermined target SOC based on a degradation rate at the upper limit of the average SOC usage range being lower than a degradation rate at the predetermined target SOC, or
the second reference value is set to be the upper limit of the average SOC usage range based on a degradation rate at the upper limit of the average SOC usage range being greater than a degradation rate at the predetermined target SOC.

20. A battery system comprising:
a sensor configured to sense states of a plurality of battery cells in a battery; and
a control circuit operatively connected to the sensor,
wherein the control circuit is configured to:
detect at least one first battery cell, of the plurality of battery cells, associated with a first battery cell state, and detect at least one second battery cell, of the plurality of battery cells, associated with a second battery cell state; and
perform cell balancing of the battery by sequentially adjusting a voltage of each of the at least one second battery cell to one of a maximum voltage of the plurality of battery cells or a minimum voltage of the plurality of battery cells, such that a voltage of each of the at least one first battery cell does not correspond to the maximum voltage or the minimum voltage.
